(19) United States
(12) Patent Application Publication
(10) Pub. No.: US 2026/0150206 A1
(43) Pub. Date: May 28, 2026

(54) DISPLAY APPARATUS

(71) Applicant: LG Display Co., Ltd., Seoul (KR)

(72) Inventor: SungSik Son, Daegu (KR)

(73) Assignee: LG Display Co., Ltd., Seoul (KR)

(21) Appl. No.: 19/199,054

(22) Filed: May 5, 2025

(30) Foreign Application Priority Data
Nov. 28, 2024 (KR) 10-2024-0174058

(51) Int. Cl. H05K 5/02

(52) U.S. Cl. CPC H05K 5/0217

(57) ABSTRACT

Provided is a display apparatus. The display apparatus comprises a transparent display panel, a light-shielding sheet disposed on one surface of the transparent display panel, a roller connected to the light-shielding sheet and winding or unwinding the light-shielding sheet, and a transparent frame supporting the transparent display panel and the light-shielding sheet, wherein the transparent frame includes a side bar disposed on side portions of the transparent display panel and the light-shielding sheet to support the transparent display panel and the light-shielding sheet, and the side bar includes a groove that accommodates both ends of the light-shielding sheet and is configured to guide movement of the light-shielding sheet.

### CROSS-REFERENCE TO RELATED APPLICATION

This application claims the benefit and priority to Korean Patent Application No. 10-2024-0174058, filed in the Republic of Korea on Nov. 28, 2024, the entirety disclosure of which is incorporated herein by reference for all purposes.

### BACKGROUND

### Technical Field

The present disclosure relates to a display apparatus and, more specifically to, for example, without limitation, a display apparatus in which a transparent display panel can be selectively covered by a light-shielding sheet.

### Description of the Related Art

As display apparatus which are used for a monitor of a computer, a television, a cellular phone, or the like, there are an organic light emitting display (OLED) device which is a self-emitting device, a liquid crystal display (LCD) device which requires a separate light source, and the like.

An applicable range of the display apparatus is diversified to personal digital assistants as well as monitors of computers and televisions and a display apparatus with a large display area and a reduced volume and weight is being studied.

In addition, research on transparent display panels has been actively conducted recently. The transparent display panel refers to a display panel that allows a user to recognize not only visual information implemented in the transparent display panel on the front surface of the panel, but also an object located on the rear surface of the transparent display panel. Thus, the transparent display panel of the display apparatus includes a light-emitting area in which an image is implemented and a transparent area through which external light is transmitted.

The description provided in the background section should not be assumed to be prior art merely because it is mentioned in or associated with the background section. The background section may include information that describes one or more aspects of the subject technology.

### SUMMARY

However, it is newly recognized by the inventor of the present application that, since the transparent display panel allows external light to be transmitted through the transparent area, there is a limitation in which external light is recognized by a viewer while the image is being driven, thereby reducing the visibility of the image.

Therefore, the inventor of the present disclosure recognized the limitation mentioned above and other limitations associated with the related art, and conducted various experiments to implement a display apparatus in which a transparent display panel of the display apparatus may be selectively opened or shielded.

Another aspect of the present disclosure is to provide a display apparatus with reduced space, including a frame that supports a transparent display panel and a light-shielding sheet together.

Still another aspect of the present disclosure is to provide a display apparatus with improved visibility by applying a transparent frame structure.

Still another aspect of the present disclosure is to provide a display apparatus with a simplified structure.

Aspects and features of the present disclosure are not limited to the above-mentioned aspects and features, and other aspects and features, which are not mentioned above, can be clearly understood by those skilled in the art from the following descriptions.

To achieve these and other aspects of the inventive concepts, as embodied and broadly described herein, there is provided a display apparatus. The display apparatus comprises a transparent display panel, and a light-shielding sheet disposed on one surface of the transparent display panel, wherein the light-shielding sheet is rollable. The display apparatus may further comprises a roller connected to the light-shielding sheet and winding or unwinding the light-shielding sheet; and a transparent frame supporting the transparent display panel and the light-shielding sheet, wherein the transparent frame includes a side bar disposed on side portions of the transparent display panel and the light-shielding sheet to support the transparent display panel and the light-shielding sheet, and the side bar includes a groove that accommodates both ends of the light-shielding sheet and is configured to guide movement of the light-shielding sheet.

According to another aspect of the present disclosure, there is provided a display apparatus. The display apparatus comprises a housing unit, a roller accommodated in the housing unit, a transparent display panel exposed to an outside of the housing unit, and a light-shielding sheet connected to the roller and accommodated in the housing unit or exposed to the outside of the housing unit. The display apparatus may further comprise a frame surrounding a periphery of the transparent display panel, wherein when the light-shielding sheet is fully unwound, the frame surrounds both a periphery of the light-shielding sheet and the periphery of the transparent display panel.

Other detailed matters of various example embodiments are included in the detailed description and the drawings.

The present disclosure provides a display apparatus that can open or shield the transparent display panel by winding or unwinding the light-shielding sheet.

The present disclosure can simplify the support structure of the transparent display panel and the light-shielding sheet by using an integrated frame.

The present disclosure can reduce the volume and weight of the display apparatus by simplifying the structure.

The effects of the present disclosure are not limited to the aforementioned effects, and other effects, which are not mentioned above, will be apparently understood to a person having ordinary skill in the art from the following description.

It is to be understood that both the foregoing general description and the following detailed description are by way of example and explanatory and are intended to provide further explanation of the inventive concepts as claimed.

### BRIEF DESCRIPTION OF DRAWINGS

The accompanying drawings, that may be included to provide a further understanding of the disclosure and may be incorporated in and constitute a part of the disclosure, illustrate example embodiments of the disclosure and together with the description serve to explain various principles of the disclosure. The above and other aspects, features, and other advantages of the present disclosure will be more clearly understood from the following detailed description taken in conjunction with the accompanying drawings, in which:

FIG. 1 is a view illustrating an apparatus to which a display apparatus according to an example embodiment of the present disclosure is applied;

FIGS. 2A to 2C are perspective views of the display apparatus according to an example embodiment of the present disclosure;

FIGS. 3A and 3B are perspective views of the display apparatus according to an example embodiment of the present disclosure;

FIG. 4 is a cross-sectional view taken along line A-A′ of FIG. 2A;

FIG. 5A is a cross-sectional view taken along line B-B′ of FIG. 2B; and

FIG. 5B is a cross-sectional view taken along line C-C′ of FIG. 2B.

Throughout the drawings and the detailed description, unless otherwise described, the same drawing reference numerals should be understood to refer to the same or similar elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, where a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and characteristics of the present disclosure and a method of achieving the advantages and characteristics will be clear by referring to example embodiments described below in detail together with the accompanying drawings. However, the present disclosure is not limited to the example embodiments disclosed herein but can be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with a more limiting term, such as “only”. Any references to singular may include plural, and vice versa, unless expressly stated otherwise.

Components are interpreted to include an ordinary error range or tolerance range even if there is no explicit description of such an error or tolerance range.

In describing a time relationship, for example, where the temporal order is described as, for example, “after,” “subsequent,” “next,” and “before,” a case which is not continuous may be included unless a more limiting term, such as “just,” “immediate(ly),” or “direct(ly),” is used.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly),” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

When an element or layer is disposed “on” another element or layer, another layer or another element may be interposed directly on the other element or therebetween.

Although the terms such as “first”, “second”, “A,” “B,” “(a),” “(b)” and the like are used for describing various components, these components are not confined by these terms. These terms are merely used for referring to one component separately from the other components. Therefore, a first component to be mentioned below may be a second component, and vice versa, in a technical concept of the present disclosure. Also, where an element or layer is described as being “connected,” “coupled,” or “adhered” to another element or layer, the element or layer can not only be directly connected, or adhered to that other element or layer, but also be indirectly connected, or adhered to that other another element or layer with one or more intervening elements or layers “disposed” between the elements or layers, unless otherwise specified.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various example embodiments of the present disclosure will be described in detail with reference to the drawings. Further, all the components of each display apparatus according to all embodiments of the present disclosure can be operatively coupled and configured.

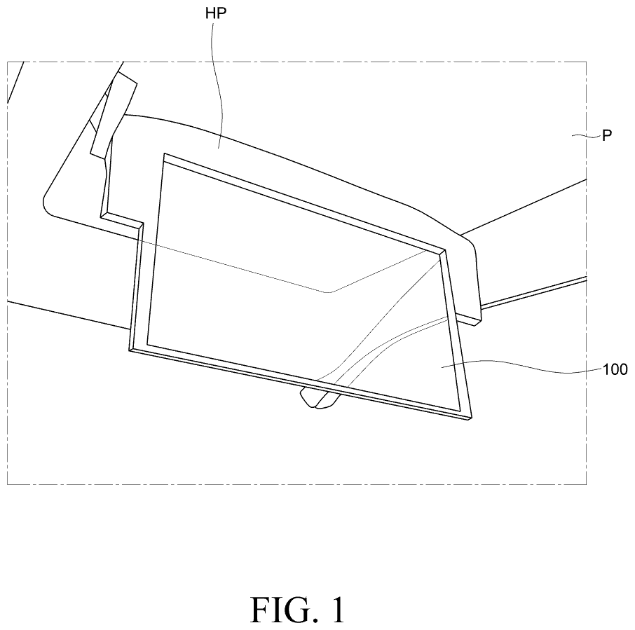

FIG. 1 is a view illustrating an apparatus (e.g., a vehicle apparatus or an electronic apparatus) to which a display apparatus according to an example embodiment of the present disclosure is applied.

A display apparatus 100 according to an example embodiment of the present disclosure may be a vehicle display apparatus. The display apparatus 100 may be fixed inside a vehicle. For example, the display apparatus 100 may be mounted on a roof panel P of a vehicle. The display apparatus 100 may be disposed so as to be inclined on the roof panel P to provide information such as movies, news, and entertainment to a passenger, and may also be used for purposes such as video conferencing.

The display apparatus 100 may include a transparent display module and a light-shielding sheet. In this case, when the light-shielding sheet is configured to cover one surface of the transparent display module, external light incident on the display apparatus 100 may be shielded. In addition, when the light-shielding sheet is configured to be accommodated in the housing unit HP to expose one surface of the transparent display module, light incident on a surface of the display apparatus 100 may pass through the display apparatus 100. Accordingly, the passenger may recognize the background of the rear surface of the display apparatus 100, and the display apparatus 100 may secure a field of view even in a limited space inside the vehicle, thereby improving aesthetics.

In addition, the display apparatus 100 may include a lifting unit that disposes the light-shielding sheet outside the housing unit HP or moves the light-shielding sheet into the housing unit HP.

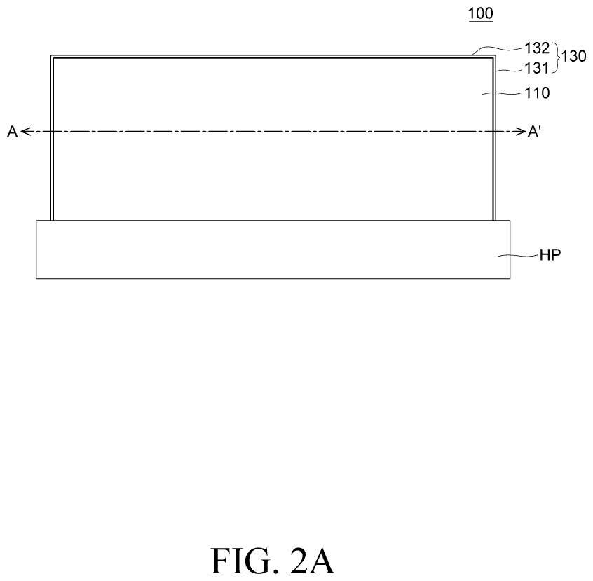

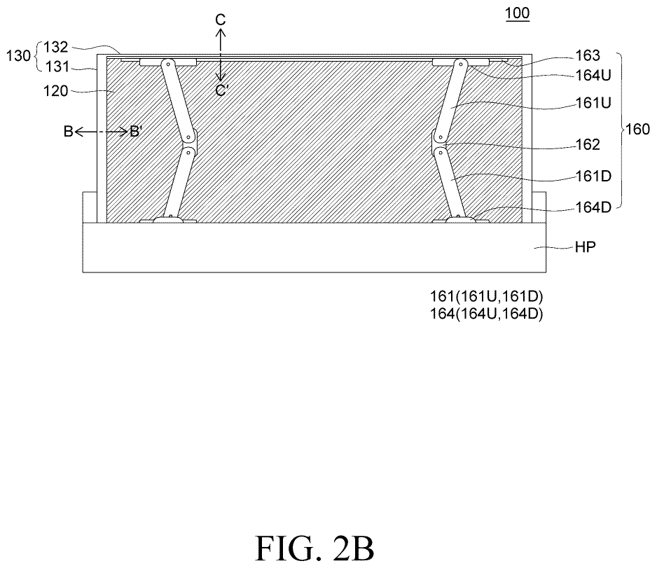

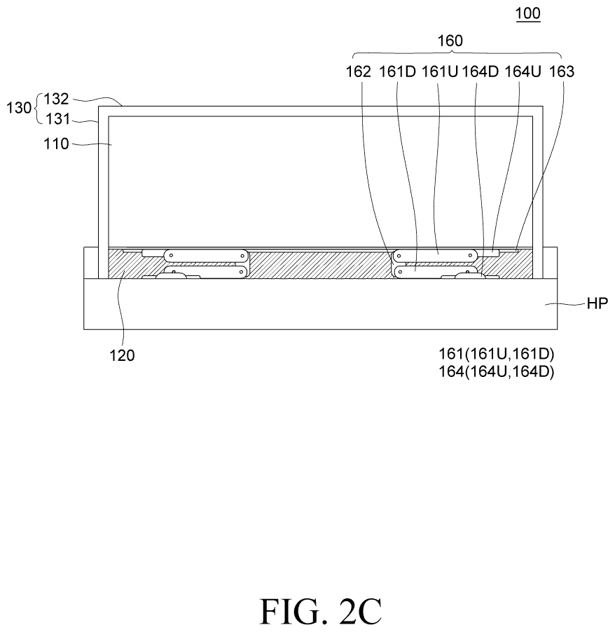

Hereinafter, with reference to FIGS. 2A to 5B, a display apparatus 100 according to an example embodiment of the present disclosure will be described in detail. In addition, in FIG. 1, the housing unit HP is disposed at the upper end portion of the display apparatus 100 and the upper end portion of the display apparatus 100 is fixed, but in FIGS. 2A to 5B, for convenience of explanation, the housing unit HP is disposed at the lower end portion of the display apparatus 100 and the lower end portion of the display apparatus 100 is fixed.

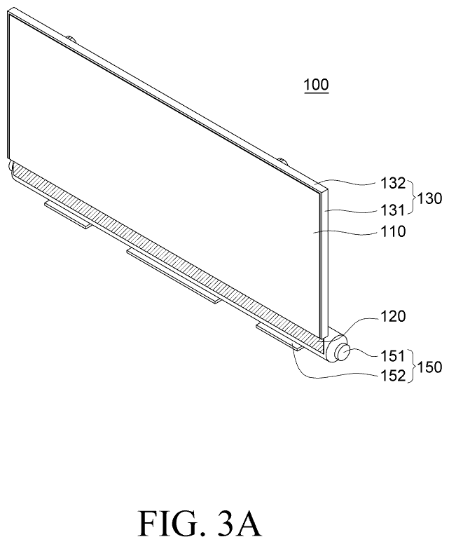

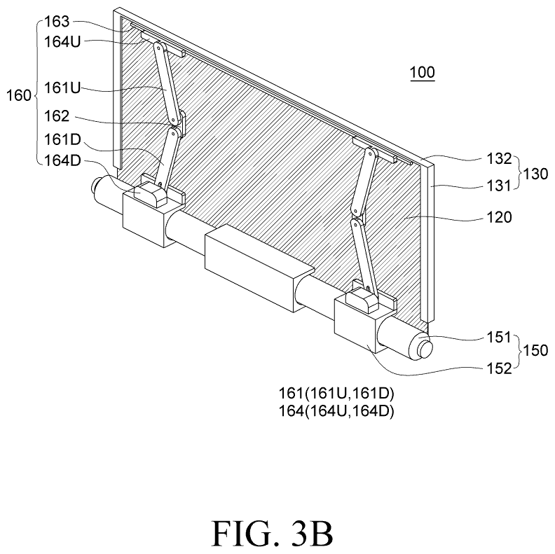

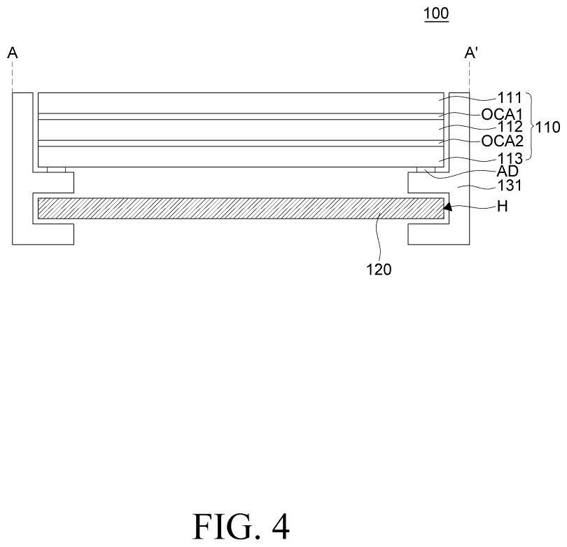

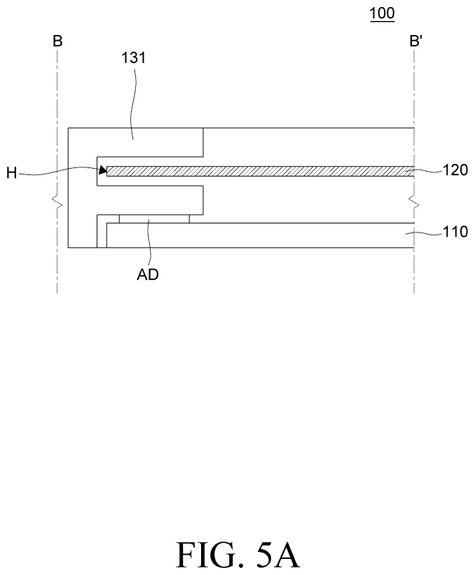

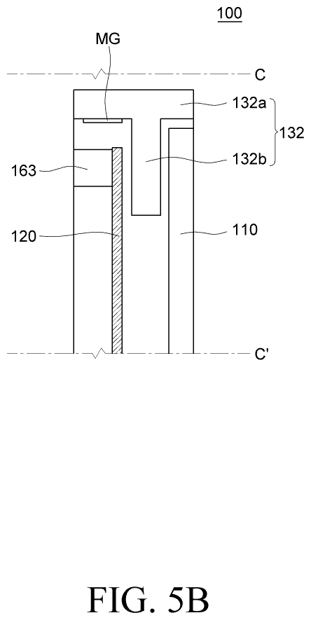

FIGS. 2A to 2C are perspective views of the display apparatus according to an example embodiment of the present disclosure. FIGS. 3A and 3B are perspective views of the display apparatus according to an example embodiment of the present disclosure. FIG. 4 is a cross-sectional view taken along line A-A′ of FIG. 2A. FIG. 5A is a cross-sectional view taken along line B-B′ of FIG. 2B. FIG. 5B is a cross-sectional view taken along line C-C′ of FIG. 2B. FIGS. 3A and 3B are perspective views of a display apparatus 100 according to an example embodiment of the present disclosure with the housing unit HP removed.

As shown in FIGS. 2A to 2C, the display apparatus 100 according to an example embodiment of the present disclosure includes a transparent display panel 110, a light-shielding sheet 120, a lifting unit 160, the housing unit HP, and a transparent frame 130.

The housing unit HP is a case in which the light-shielding sheet 120 can be accommodated.

One surface of the housing unit HP may be opened so that the light-shielding sheet 120 can move into and out of the housing unit HP.

The transparent display panel 110 is a panel for displaying an image to a user.

The transparent display panel 110 may include a display element layer 113, a color filter layer 112, a cover window 111, a first optical adhesive layer OCA1, and a second optical adhesive layer OCA2.

As shown in FIG. 4, the cover window 111 has a shape corresponding to the display element layer 113 and may be disposed to cover the display element layer 113. The cover window 111 may protect the display element layer 113 from external impact, moisture, heat, or the like.

The first optical adhesive layer OCA1 may be disposed between the cover window 111 and the color filter layer 112. The first optical adhesive layer OCA1 may fix the color filter layer 112 and the cover window 111. The first optical adhesive layer OCA1 may be formed of an optically clear adhesive (OCA) that minimizes or at least partially reduces the occurrence of foreign materials or bubbles between the color filter layer 112 and the cover window 111, but is not limited thereto.

The color filter layer 112 may be disposed on the rear surface of the first optical adhesive layer OCA1. The color filter layer 112 may include a red color filter, a green color filter, and a blue color filter. In addition, the color filter layer 112 may further include a black matrix layer, but is not limited thereto. In addition, the color filter layer 112 may be omitted according to an implementation example of the display apparatus 100. For example, when the display element layer 113 is formed of an organic/inorganic light-emitting display device layer in which pixels or subpixels emit lights of various colors independently, the color filter layer 112 as well as the first optical adhesive layer OCA1 may be omitted. In that case, the display element layer 113 is fixed to the cover window 111 via the second optical adhesive layer OCA2.

The second optical adhesive layer OCA2 may be disposed between the color filter layer 112 and the display element layer 113. The second optical adhesive layer OCA2 may fix the color filter layer 112 and the display element layer 113. The second optical adhesive layer OCA2 may be formed of an optically clear adhesive (OCA) that minimizes or at least partially reduces the occurrence of foreign materials or bubbles between the color filter layer 112 and the display element layer 113, but is not limited thereto.

The display element layer 113 may be disposed on the rear surface of the color filter layer 112.

The display element layer 113 is a panel for displaying an image to the user. On the display element layer 113, a light-emitting diode for displaying an image, a driving element for driving the light-emitting diode, a line for transmitting various signals to the light-emitting diode and the driving element, or the like may be disposed.

The light-emitting diode may be defined differently depending on the type of the transparent display panel 110. For example, when the transparent display panel 110 is an organic light-emitting transparent display panel 110, the light-emitting diode may be an organic light-emitting diode including an anode, an organic light-emitting layer, and a cathode, but the present disclosure is not limited thereto. In the following description, it is assumed that the transparent display panel 110 is an organic light-emitting transparent display panel, but the transparent display panel 110 is not limited to the organic light-emitting transparent display panel.

The transparent display panel 110 may be exposed to the outside of the housing unit HP and attached to the transparent frame 130. For example, the transparent display panel 110 may be attached to the transparent frame 130 through an adhesive layer AD disposed between the transparent display panel 110 and the transparent frame 130. The adhesive layer AD will be described in detail later together with the transparent frame 130.

The light-shielding sheet 120 may be disposed on one surface of the transparent display panel 110. The light-shielding sheet 120 may be disposed on one surface of the transparent display panel 110 to control the transmitting or blocking of external light.

As shown in FIGS. 3A and 3B, the light-shielding sheet 120 may be configured to be rollable, woundable or wrappable. The light-shielding sheet 120 may include a flexible material. For example, the light-shielding sheet 120 of the display apparatus 100 may be switched from a fully unwound state to a fully wound state, or from the fully wound state to the fully unwound state, by the movement of a roller 151 of the roller unit 150. For example, when the roller 151 rotates in a first direction, the light-shielding sheet 120 wound around the roller 151 may be unwounded from the roller 151 and disposed outside the housing unit HP, and when the roller 151 rotates in a second direction opposite to the first direction, the light-shielding sheet 120 disposed outside the housing unit HP may be wound around the roller 151 and accommodated in the housing unit HP. The first direction and the second direction may be clockwise and counterclockwise, respectively, but are not limited thereto.

In FIG. 2A, FIG. 2B, FIG. 3A, and FIG. 3B, the light-shielding sheet 120 of the display apparatus 100 is illustrated in a fully unwound state. The fully unwound light-shielding sheet 120 is in a state in which the light-shielding sheet 120 is disposed outside the housing unit HP. In other words, the state in which the light-shielding sheet 120 is disposed outside the housing unit HP to the maximum extent and cannot be unwound any more may be defined as the fully unwound state. In another example, the state in which the light-shielding sheet 120 is disposed outside the housing unit HP to fully cover the transparent display panel 110 may be defined as the fully unwound state. In other words, when the light-shielding sheet 120 is fully unwound, the light-shielding sheet 120 may shield external light incident on the transparent display panel 110.

FIG. 2C illustrates a state in which the light-shielding sheet 120 of the display apparatus 100 is fully wound. The fully wound light-shielding sheet 120 may be defined as being in a state in which the light-shielding sheet 120 is accommodated to the maximum extent within the housing unit HP and cannot be wound any further. For example, when the light-shielding sheet 120 is fully wound, the light-shielding sheet 120 exposes one surface of the transparent display panel 110 so that light incident on the transparent display panel 110 may be transmitted.

In addition, as shown in FIG. 3A and FIG. 3B, the roller unit 150 and the lifting unit 160 that wind or unwind the light-shielding sheet 120 to raise or lower the end of the light-shielding sheet 120 are disposed. However, the present disclosure is not limited thereto, and various other structures or mechanisms for controlling the winding or unwinding of the the light-shielding sheet 120 may be disposed instead of the roller unit 150 and the lifting unit 160.

The display apparatus 100 includes the roller unit 150 and the lifting unit 160.

The roller unit 150 may be accommodated in the housing unit HP. The roller unit 150 rotates clockwise or counterclockwise and winds or unwinds the light-shielding sheet 120 fixed to the roller unit 150. The roller unit 150 includes the roller 151 and a roller support portion 152.

The roller 151 is a member around which the light-shielding sheet 120 is wound. The roller 151 may be formed, for example, in a cylindrical shape. The lower edge of the light-shielding sheet 120 may be fixed to the roller 151. When the roller 151 rotates, the light-shielding sheet 120 whose lower edge is fixed to the roller 151 may be wound around the roller 151. In addition, when the roller 151 rotates in the opposite direction, the light-shielding sheet 120 wound around the roller 151 may be unwound from the roller 151.

The roller support portions 152 support the roller 151 on both sides of the roller 151. Specifically, the roller support portion 152 may support the roller 151 so that the roller 151 is spaced apart from the bottom surface of the housing unit HP. In this case, the roller 151 may be rotatably coupled to the roller support portion 152.

The lifting unit 160 moves the light-shielding sheet 120 up and down in accordance with the operation of the roller unit 150. The lifting unit 160 includes a plurality of links 161, a link connection portion 162, a head bar 163, and a support shaft 164.

Each of the plurality of links 161 is connected to the upper side of a display unit DP. For example, one end of each of the plurality of links 161 is connected to both ends of the upper edge of the light-shielding sheet 120, so that the light-shielding sheet 120 unwound from the roller 151 may be supported so as to remain flat.

Each of the plurality of links 161 includes an upper link 161U and a lower link 161D. The upper link 161U and the lower link 161D are rotatably coupled to each other and may be folded or unfolded. For example, the upper link 161U and the lower link 161D may be folded by rotating in a direction toward each other, and the upper link 161U and the lower link 161D may be unfolded by rotating in a direction away from each other.

One end of the upper link 161U is rotatably coupled to both ends of the upper edge of the light-shielding sheet 120. Specifically, one end of the upper link 161U is rotatably coupled to the head bar 163 fixed to the upper edge of the light-shielding sheet 120.

The head bar 163 is a member for connecting the light-shielding sheet 120 and the upper link 161U. The head bar 163 may be fixed to the upper edge of the light-shielding sheet 120. For example, the light-shielding sheet 120 and the head bar 163 may be fixed with screws, but are not limited thereto.

The upper link 161U is rotatably connected to the head bar 163, and the head bar 163 may move up and down according to the rotation of the upper link 161U. Accordingly, the light-shielding sheet 120 fixed to the head bar 163 may also move up and down along the head bar 163.

The support shaft 164 includes an upper support shaft 164U and a lower support shaft 164D.

One end of the upper link 161U may rotate around the upper support shaft 164U. The upper support shaft 164U is rotatably connected to one end of the upper link 161U, and one end of the upper link 161U may be fixed to the head bar 163.

The other end of the upper link 161U is rotatably coupled to one end of the lower link 161D. For example, a gear may be further disposed on the other end of the upper link 161U so that the other end of the upper link 161U can be rotatably coupled to one end of the lower link 161D, but is not limited thereto.

One end of the lower link 161D is rotatably connected to the other end of the upper link 161U. One end of the lower link 161D may be further disposed of by the gear, similar to the other end of the upper link 161U, but is not limited thereto.

In addition, the link connection portion 162 is disposed at the other end of the upper link 161U and one end of the lower link 161D. The shaft of the gear of the other end of the upper link 161U and the shaft of the gear of one end of the lower link 161D are connected to the link connection portion 162, respectively. Accordingly, the gear of the other end of the upper link 161U may rotate around the shaft connected to the link connection portion 162, and the gear of one end of the lower link 161D may rotate around the shaft connected to the link connection portion 162. In addition, the teeth of the gear of the other end of the upper link 161U and the teeth of the gear of one end of the lower link 161D mesh with each other, so that the upper link 161U may also rotate according to the rotation of the lower link 161D, and the lower link 161D may also rotate according to the rotation of the upper link 161U.

In addition, although not illustrated in the drawings, the other end of the lower link 161D may be connected to a driving unit that enables the other end of the lower link 161D to rotate. The driving unit may be a motor that can be supplied with power by being connected to a power generation unit such as a separate external power source or a built-in battery, but is not limited thereto.

At any point between one end and the other end of the lower link 161D, the lower link 161D is rotatably coupled to the lower support shaft 164D. Accordingly, the lower link 161D may rotate about the lower support shaft 164D and raise the lower link 161D.

The lower support shaft 164D may be disposed to be spaced apart from the bottom surface of the housing unit HP. When the other end of the lower link 161D rotates, the lower support shaft 164D may be disposed to be spaced apart from the bottom surface of the housing unit HP so that the other end of the lower link 161D and the bottom surface of the housing unit HP do not interfere with each other.

In addition, the head bar 163 may include a material made of a magnetic body. The head bar 163 may include a material made of a magnetic body to fix the light-shielding sheet 120 to an upper bar 132 of the transparent frame 130. The details of the head bar 163 fixing the light-shielding sheet 120 will be described in detail later together with the transparent frame 130.

As shown in FIGS. 2A to 3B, the light-shielding sheet 120 may be disposed outside the housing unit HP by the movement of the lifting unit 160. The light-shielding sheet 120 disposed outside the housing unit HP may be supported by the transparent frame 130.

The transparent frame 130 may surround the periphery of the transparent display panel 110. In addition, the transparent frame 130 may surround the periphery of the light-shielding sheet 120 together with the transparent display panel 110 when the light-shielding sheet 120 is fully unwound. For example, the transparent frame 130 includes side bars 131 disposed on the side portions of the transparent display panel 110 and the light-shielding sheet 120 to support the transparent display panel 110 and the light-shielding sheet 120, and the upper bar 132 disposed on the upper portions of the transparent display panel 110 and the light-shielding sheet 120 to protect the transparent display panel 110 and the light-shielding sheet 120.

As shown in FIGS. 2A to 2C, the side bar 131 of the transparent frame 130 is coupled to the front portion of the housing unit HP. The side bar 131 may have a lower edge fixed to the housing unit HP to support the side portions of the transparent display panel 110 and the light-shielding sheet 120. For example, the side bar 131 may fix the transparent display panel 110 so that the transparent display panel 110 is not lowered and maintains an unfolded state. For example, as shown in FIG. 4, the adhesive layer AD is attached to the side bar 131. In addition, both side portions of the transparent display panel 110 overlapping the side bar 131 may be attached to the side bar 131 of the transparent frame 130 via the adhesive layer AD.

In addition, as shown in FIG. 4 and FIG. 5A, the transparent frame 130 includes a guide groove H along which the end of the light-shielding sheet 120 slides. The guide groove H may be disposed on the side bar 131 of the transparent frame 130. The guide groove H accommodates both ends of the light-shielding sheet 120 and may guide the movement of the light-shielding sheet 120. Accordingly, the light-shielding sheet 120 may slide with respect to the guide groove H of the side bar 131 and move up and down. Accordingly, the side bar 131 may support the light-shielding sheet 120 on both sides so that the light-shielding sheet 120 may move up and down smoothly.

The upper bar 132 of the transparent frame 130 may be disposed on the upper ends of the transparent display panel 110 and the light-shielding sheet 120 to support the transparent display panel 110 and the light-shielding sheet 120. The upper bar 132 may be formed integrally with the side bar 131. For example, the upper bar 132 may be formed of the same material as the side bar 131 to support the upper ends and side portions of the transparent display panel 110 and the light-shielding sheet 120.

As shown in FIG. 5B, the upper bar 132 may include a first portion 132a disposed on the upper end of the transparent display panel 110 and a second portion 132b extending from the first portion 132a between the transparent display panel 110 and the light-shielding sheet 120.

The first portion 132a may be disposed on the upper portions of the transparent display panel 110 and the light-shielding sheet 120 to cover the upper portions of the transparent display panel 110 and the light-shielding sheet 120. Accordingly, the first portion 132a may protect the transparent display panel 110 and the light-shielding sheet 120 from the outside.

A magnet MG may be disposed in the first portion 132a. The magnet MG may extend along the direction in which the first portion 132a is disposed, and may cover the upper portion of the light-shielding sheet 120. For example, the magnet MG may be disposed to overlap the head bar 163. The magnet MG may attach or detach the light-shielding sheet 120 to the upper bar 132. For example, when the head bar 163 includes a material made of a magnetic body, an attractive force may be generated between the magnet MG and the head bar 163. Therefore, the attractive force generated between the magnet MG and the head bar 163 may fix the light-shielding sheet 120 so that the light-shielding sheet 120 is not wound around the roller 151 in a state where the light-shielding sheet 120 is in a fully unwound state. For example, the attractive force generated between the magnet MG and the head bar 163 enables the light-shielding sheet 120 to maintain the fully unwound state on the roller 151, and also enables the plurality of links 161 connected to the head bar 163 of the upper edge of the light-shielding sheet 120 to maintain an unfolded state without being lowered. In this case, the longitudinal direction of the head bar 163 may provide a fixing force for the longitudinal direction of the light-shielding sheet 120, and the attractive force generated between the magnet MG and the head bar 163 may provide a fixing force for the height direction of the light-shielding sheet 120.

In addition, when the head bar 163 does not include a material made of a magnetic body, a separate magnetic material may be disposed at the upper portion of the light-shielding sheet 120. For example, the magnet MG disposed at the first portion 132a may be referred to as a first magnet, and the magnetic material disposed at the upper portion of the light-shielding sheet 120 may be referred to as a second magnet. In this case, the attractive force generated between the first magnet and the second magnet may fix the light-shielding sheet 120 so that the light-shielding sheet 120 is not wound around the roller 151 in the state where the light-shielding sheet 120 is in the fully unwound state.

The second portion 132b may suppress the damage of the transparent display panel 110 when the light-shielding sheet 120 moves up and down by spacing the transparent display panel 110 and the light-shielding sheet 120 from each other.

The transparent display panel refers to a display panel that allows a user to recognize not only visual information implemented on the transparent display panel on the front surface of the panel, but also an object or the like located on the rear surface of the transparent display panel. Thus, the transparent display panel of the display apparatus includes a light-emitting area where an image is implemented, and a transparent area through which external light passes. In addition, since the transparent display panel allows external light to pass through the transparent area, there is a limitation in that the visibility of the image is reduced because the external light is recognized by the viewer while the image is being driven.

Accordingly, in the display apparatus 100 according to an example embodiment of the present disclosure, one surface of the transparent display panel 110 is selectively covered by the light-shielding sheet 120, so that a transparent mode and a shielding mode may be selectively implemented. For example, the display apparatus 100 according to an example embodiment of the present disclosure includes the light-shielding sheet 120 which can be switched between the fully wound state and the fully unwound state by the movement of the roller 151. Accordingly, when the light-shielding sheet 120 is fully wound, one surface of the transparent display panel 110 is exposed, so that the transparent mode which shows the rear of the transparent display panel 110 may be implemented. In addition, when the light-shielding sheet 120 is fully unwound, the light-shielding sheet 120 covers one surface of the transparent display panel 110, so that the shielding mode in which light incident on the transparent display panel 110 may be shielded may be implemented. Therefore, the visibility of the image of the display apparatus 100 may be improved.

In addition, in the display apparatus 100 according to an example embodiment of the present disclosure, the transparent frame 130 supporting the transparent display panel 110 and the light-shielding sheet 120 is made of a transparent material. Accordingly, compared to a case where the frame supporting the transparent display panel 110 and the light-shielding sheet 120 is made of an opaque material, the aesthetics may be improved, and the visibility may also be improved. However, the present disclosure is not limited thereto, and the frame 130 supporting the transparent display panel 110 and the light-shielding sheet 120 is made of an opaque material or a translucent material, and the transparent frame 130 is provided herein by way of example only.

In addition, in the display apparatus 100 according to an example embodiment of the present disclosure, the transparent frame 130 supporting the transparent display panel 110 also supports the light-shielding sheet 120. For example, the transparent frame 130 supporting the transparent display panel 110 includes the guide groove H through which the end of the light-shielding sheet 120 slides. Accordingly, the light-shielding sheet 120 may slide and move up and down with respect to the guide groove H of the transparent frame 130. Therefore, compared to a case where the frame supporting the transparent display panel 110 and the frame supporting the light-shielding sheet 120 are provided separately, the frame structure may be simplified, and the space may be reduced. Therefore, the display apparatus 100 according to an example embodiment of the present disclosure may have a simplified structure and may also have a reduced volume and weight.

Various example embodiments of the present disclosure can also be described as follows:

According to an aspect of the present disclosure, there is provided a display apparatus. The display apparatus comprises a transparent display panel, and a light-shielding sheet disposed on one surface of the transparent display panel, wherein the light-shielding sheet is rollable. The display apparatus may further comprise a roller connected to the light-shielding sheet and winding or unwinding the light-shielding sheet; and a transparent frame supporting the transparent display panel and the light-shielding sheet, wherein the transparent frame includes a plurality of side bars disposed on side portions of the transparent display panel and the light-shielding sheet to support the transparent display panel and the light-shielding sheet, and the plurality of side bars include a groove that accommodates both ends of the light-shielding sheet and is configured to guide movement of the light-shielding sheet.

The transparent frame may further include an upper bar extended from the plurality of side bars and disposed on the transparent display panel and the light-shielding sheet, and the upper bar may include a first portion disposed on an upper end of the transparent display panel, and a second portion extended from the first portion between the transparent display panel and the light-shielding sheet.

The upper bar and the plurality of side bars may be integrated with each other.

The display apparatus may further comprise a first magnet disposed in the first portion, and a second magnet disposed in an upper end of the light-shielding sheet to attach or detach the light-shielding sheet to the upper bar, wherein an attractive force generated between the first magnet and the second magnet may fixe the light-shielding sheet so that the light-shielding sheet is not wound around the roller when the light-shielding sheet is in a fully unwound state.

The display apparatus may further comprise an adhesive layer disposed between the transparent frame and the transparent display panel, wherein the transparent display panel may be attached to the transparent frame by the adhesive layer.

The display apparatus may further comprise a motor, and a lifting unit disposed on one surface of the light-shielding sheet, wherein the motor may raise or lower an end of the light-shielding sheet through the lifting unit.

The display apparatus may further comprise a housing unit that accommodates the roller, wherein a lower edge of the side bar may be fixed to the housing unit.

The light-shielding sheet may be disposed to fully cover the transparent display panel in a state where the light-shielding sheet is in a fully unwound state.

According to another aspect of the present disclosure, there is provided a display apparatus. The display apparatus comprises a housing unit, a roller accommodated in the housing unit, a transparent display panel exposed to an outside of the housing unit, and a light-shielding sheet connected to the roller and accommodated in the housing unit or exposed to the outside of the housing unit. The display apparatus may further comprise a frame surrounding a periphery of the transparent display panel, wherein when the light-shielding sheet is fully unwound, the frame surrounds both a periphery of the light-shielding sheet and the periphery of the transparent display panel.

The frame may include a plurality of guide grooves accommodating a portion of both ends of the light-shielding sheet, and the light-shielding sheet may slide along the plurality of guide grooves.

The frame may include a plurality of side bars disposed on a side portion of the transparent display panel, and an upper bar extended from the side bar and disposed on an upper end of the transparent display panel, and the plurality of guide grooves may be disposed on the plurality of side bars.

The display apparatus may further comprise an adhesive layer disposed between the plurality of side bars and the transparent display panel, wherein the transparent display panel may be attached to the plurality of side bars by the adhesive layer.

The display apparatus may further comprise a motor, and a lifting unit disposed on one surface of the light-shielding sheet, wherein the lifting unit may raise or lower the light-shielding sheet by the motor.

The display apparatus may further comprise a magnet disposed in the frame, wherein the lifting unit may include a head bar disposed corresponding to an upper edge of the light-shielding sheet, and the magnet may be disposed to overlap the head bar.

The head bar may include a magnetic material, and an attractive force generated between the magnet and the head bar may fixe the light-shielding sheet so that the light-shielding sheet is not wound around the roller in a state where the light-shielding sheet is in a fully unwound state.

The frame may be transparent.

The display apparatus may be fixed inside a vehicle.

According to yet another aspect of the present disclosure, there is provided a display apparatus. The display apparatus may include a transparent display panel including a light-emitting area in which an image is displayed and a transparent area through which external light is transmitted; and a light-shielding sheet disposed on a rear surface of the transparent display panel and switchable between a fully wound state and a fully unwound state depending on an operation mode of the display apparatus, wherein the operation mode includes a transparent mode and a shielding mode.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims and their equivalents, and all the technical concepts in the equivalent scope thereof should be construed as falling within the scope of the present disclosure.

What is claimed is:

1. A display apparatus, comprising:
a transparent display panel; and
a light-shielding sheet disposed on one surface of the transparent display panel,
wherein the light-shielding sheet is rollable.

2. The display apparatus of claim 1, further comprising:
a roller connected to the light-shielding sheet and configured to wind or unwind the light-shielding sheet; and
a transparent frame supporting the transparent display panel and the light-shielding sheet,
wherein the transparent frame includes a plurality of side bars disposed on side portions of the transparent display panel and the light-shielding sheet to support the transparent display panel and the light-shielding sheet, and
wherein the plurality of side bars include a groove that accommodates both ends of the light-shielding sheet and is configured to guide movement of the light-shielding sheet.

3. The display apparatus of claim 2, wherein:
the transparent frame further includes an upper bar extended from the plurality of side bars and disposed on the transparent display panel and the light-shielding sheet; and
the upper bar includes:
a first portion disposed on an upper end of the transparent display panel; and
a second portion extended from the first portion between the transparent display panel and the light-shielding sheet.

4. The display apparatus of claim 3, wherein the upper bar and the plurality of side bars are integrated with each other.

5. The display apparatus of claim 3, further comprising:
a first magnet disposed in the first portion; and
a second magnet disposed in an upper end of the light-shielding sheet to attach or detach the light-shielding sheet to the upper bar,
wherein an attractive force generated between the first magnet and the second magnet fixes the light-shielding sheet so that the light-shielding sheet is not wound around the roller when the light-shielding sheet is in a fully unwound state.

6. The display apparatus of claim 2, further comprising an adhesive layer disposed between the transparent frame and the transparent display panel,
wherein the transparent display panel is attached to the transparent frame by the adhesive layer.

7. The display apparatus of claim 1, further comprising:
a motor; and
a lifting unit disposed on one surface of the light-shielding sheet,
wherein the motor is configured to raise or lower an end of the light-shielding sheet through the lifting unit.

8. The display apparatus of claim 2, further comprising a housing unit that accommodates the roller,
wherein a lower edge of at least one of the side bars is fixed to the housing unit.

9. The display apparatus of claim 1, wherein the light-shielding sheet is disposed to fully cover the transparent display panel in a state where the light-shielding sheet is in a fully unwound state.

10. A display apparatus, comprising:
a housing unit;
a roller accommodated in the housing unit;
a transparent display panel exposed to an outside of the housing unit; and
a light-shielding sheet connected to the roller and accommodated in the housing unit or exposed to the outside of the housing unit.

11. The display apparatus of claim 10, further comprising:
a frame surrounding a periphery of the transparent display panel,
wherein when the light-shielding sheet is fully unwound, the frame surrounds both a periphery of the light-shielding sheet and the periphery of the transparent display panel.

12. The display apparatus of claim 11, wherein:
the frame includes a plurality of guide grooves accommodating a portion of both ends of the light-shielding sheet; and
the light-shielding sheet slides along the plurality of guide grooves.

13. The display apparatus of claim 12, wherein:
the frame includes:
a plurality of side bars disposed on a side portion of the transparent display panel; and
an upper bar extended from the side bar and disposed on an upper end of the transparent display panel; and
the plurality of guide grooves are disposed on the plurality of side bars.

14. The display apparatus of claim 13, further comprising an adhesive layer disposed between the plurality of side bars and the transparent display panel,
wherein the transparent display panel is attached to the plurality of side bars by the adhesive layer.

15. The display apparatus of claim 11, further comprising:
a motor; and
a lifting unit disposed on one surface of the light-shielding sheet,
wherein the lifting unit is configured to raise or lower the light-shielding sheet by the motor.

16. The display apparatus of claim 15, further comprising a magnet disposed in the frame,
wherein the lifting unit includes a head bar disposed corresponding to an upper edge of the light-shielding sheet, and
wherein the magnet is disposed to overlap the head bar.

17. The display apparatus of claim 16, wherein:
the head bar includes a magnetic material; and
an attractive force generated between the magnet and the head bar fixes the light-shielding sheet so that the light-shielding sheet is not wound around the roller in a state where the light-shielding sheet is in a fully unwound state.

18. The display apparatus of claim 11, wherein the frame is transparent.

19. The display apparatus of claim 11, wherein the display apparatus is fixed inside a vehicle.

20. A display apparatus, comprising:
a transparent display panel including a light-emitting area in which an image is displayed and a transparent area through which external light is transmitted; and
a light-shielding sheet disposed on a rear surface of the transparent display panel and switchable between a fully wound state and a fully unwound state depending on an operation mode of the display apparatus,
wherein the operation mode includes a transparent mode and a shielding mode.
